(19) United States
(12) Patent Application Publication
(10) Pub. No.: US 2014/0111233 A1
(43) Pub. Date: Apr. 24, 2014

(54) APPARATUS, SYSTEMS AND METHODS FOR ENVIRONMENTAL CONTROLLED TESTING

(71) Applicants: Jonathan Sawyer, Boulder, CO (US); Robert Campbell, Boulder, CO (US); David Greene, Boulder, CO (US)

(72) Inventors: Jonathan Sawyer, Boulder, CO (US); Robert Campbell, Boulder, CO (US); David Greene, Boulder, CO (US)

(73) Assignee: XETAWAVE, LLC, Boulder, CO (US)

(21) Appl. No.: 13/656,494

(22) Filed: Oct. 19, 2012

(51) Int. Cl. G01R 31/00

(52) U.S. Cl. CPC G01R 31/003
USPC 324/750.03; 324/750.01

(57) ABSTRACT

Apparatus, systems and methods are provided for controlling a radio frequency board on an individualized basis and with respect to one or more environmental conditions, for example, temperature, pressure, humidity. In one embodiment, an enclosure configured to hold a single board includes one or more access portals and one or more interfaces, wherein the environment within the enclosure may be modified by applying one or more environmental modifiers to the enclosure through an access portal, and the operation of the board may be modified utilizing the one or more interfaces. In another embodiment, a system for testing a plurality of boards, each in their own enclosure is provided.

### CROSS REFERENCE TO RELATED APPLICATIONS

This application claims the benefit under 35 U.S.C. §119(e), of U.S. Provisional Patent Application No. 61/549,543 filed Oct. 20, 2011, which is incorporated herein by reference in its entirety.

### INVENTIVE FIELD

The various embodiments described herein generally relate apparatus, systems and methods for testing radio communications and/or other forms of circuit boards, and/or other components in an environment wherein the temperature, humidity pressure, radio frequency interference and other environmental factors may be controlled and quickly modified and adapted, as desired.

### BACKGROUND

To date, the testing of radio frequency electronic circuit boards and other components have often used large scale testing facilities including ovens and screening rooms in which mass produced radios are tested in racks of boards at one time. These facilities commonly require long cycling times, encounter radio frequency, electro-magnetic and other interference and require significant power usage arising from the need to test boards under operating conditions often varying from −40 Celsius to +85 Celsius. Further, such facilities are commonly not well adapted for testing the operational performance of specialized circuit boards and components, such as those designed to operate in non-standard operating conditions and environments. Further, such facilities are not designed for the individualized testing of boards and components under tightly controlled testing conditions. Accordingly, there is a need for testing apparatus, system and methodologies that enable the testing of small volumes of radio circuit boards and components and other forms of electronic circuits and/or components under individualized, highly responsive and often low power, controlled operating conditions and environments.

### SUMMARY

The various embodiments described herein are generally related to an apparatus, system or method for testing an electronic circuit board, chip or component. In at least one embodiment, such apparatus, system and/or method may include and/or utilize an apparatus having a floor, one or more perimeter wall sections, a lid, one or more access portals, and one or more interfaces. In at least one embodiment, the floor, perimeter wall sections and lid form a test cavity. An environmental modifier may be applied with respect to the test cavity using the one or more access portals. Accordingly, an operating condition of a board undergoing testing within the test cavity may be controlled by utilizing one or more of the interfaces.

In at least one embodiment, an apparatus may also be configured and/or a system or method may utilize an apparatus configured such that at least one of the floor, perimeter wall sections and lid is configured of a material designed to isolate the test cavity from an environmental condition external to the test cavity when the board is under test. Exemplary, and not by way of limitation, environmental conditions external to the test cavity from which isolation of the test cavity is provided and/or may be provided when the board is under test include various thermal conditions, one or more radio frequency signals or otherwise.

In at least one embodiment described herewith, an apparatus, system and/or method may be configured and/or utilize an apparatus configured in size so as to hold a single board. Other configurations, however, may be utilized in other embodiments. One or more of the various embodiments described herein may be configured to utilize an apparatus with one or more interfaces, wherein such interfaces may be configured, for example, to pass electrical (such as a power signal), optical or other types of signals by and between a board under test and non-testing conditions and a device external to the apparatus. Such interfaces may also and/or alternatively configured to include interfaces for sensors internal/external to the apparatus. Such interfaces may be configured to communicate signals from one or more environmental condition monitors to an external monitoring device, wherein the one or more environmental condition monitors are configured to monitor one or more environmental conditions inside the test cavity when the board is under test. One or more interfaces may include, in one or more embodiments, a control interface configured to communicate one or more control signals by and between a board under test and an external control device. Such control signals may be utilized to control the operation of a board under test in accordance with a testing protocol.

In at least one embodiment, one or more access portals may be configured to facilitate the application of one or more environmental modifiers to a test cavity, wherein a board or other component is desired to undergo testing within such cavity. One or more of such environmental modifiers may be applied to the test cavity while the board is electrically powered. In at least one embodiment, the one or more access portals may be configured to facilitate the application of one or more thermal environmental modifiers, wherein upon application of the one or more thermal environmental modifiers the board within the test cavity is exposed to a change in temperature, a change in the radio frequency environment or otherwise.

In at least one embodiment, an apparatus, system and method for testing a board or other component may include, or include the use of, a test cavity which includes an internal, to the cavity, emitter. In at least one embodiment, the internal emitter may be configured to emit a radio frequency signal when the internal emitter is activated.

In another embodiment, a process is described for testing a plurality of boards, components or otherwise. In at least one embodiment, a process may include the operation of arranging a plurality of enclosures, one for each of the plurality of boards, wherein each enclosure has a floor, a perimeter of one or more wall sections, a lid, one or more access portals and one or more interfaces, wherein the floor, perimeter wall sections and lid form a test cavity; and wherein an environmental modifier may be applied with respect to the test cavity using the one or more access portals; and wherein an operating condition of a board undergoing testing within the test cavity may be controlled utilized the one or more interfaces. In at least one embodiment, the operations may also and/or alternatively include applying a first environmental modifier to a first of the plurality of enclosures; applying a second environmental modifier to a second of the plurality of enclosures, when the plurality of enclosures includes more than two enclosures, applying an Nth environmental modifier to each of the remaining of the plurality of enclosures; and sequencing the application of each of the first environmental modifier, the second environmental modifier and the Nth environmental modifier to each of the plurality of enclosures.

In at least one embodiment, a process for testing one or more boards, components or otherwise may include the operation of sequencing a plurality of environmental modifiers applied to each enclosure such that each of the plurality of enclosures (when more than one such enclosure is provided and boards and/or components therein are designated for undergoing testing) receives the same sequence of environmental modifiers. Further, for at least one embodiment, a sequencing of a plurality of environmental modifiers when applied to two or more enclosures may result in the application of the plurality of environmental modifiers to at least one of the plurality of enclosures in a sequence that is unique with respect to at least one other of the plurality of enclosures. In at least one embodiment, a sequencing of a plurality of environmental modifiers may be applied to each of a plurality of enclosures so that the one or more of the plurality of environmental modifiers is applied in an order that is unique for each of the plurality of enclosures with respect to the sequencing of the plurality of environmental modifiers as applied to each of the other of the plurality of enclosures. In at least one embodiment, exemplary environmental modifiers may include those that modify a temperature of a test cavity within a desired range of temperatures. For example and not as by limitation, a temperature range of −40 Celsius to +85 Celsius.

### BRIEF DESCRIPTION OF THE DRAWING FIGURES

To further clarify the above and other advantages and features of the various embodiments described hereinafter, a more particular description of at least one of such embodiments will be rendered by reference to specific implementations thereof which are illustrated in the appended drawings. It is to be appreciated that these drawings depict only one or more embodiments and are therefore not to be considered limiting of any embodiments scope. The various embodiments will be described and explained with additional specificity and detail through the use of the accompanying drawings in which:

FIG. 1 depicts a testing apparatus in accordance with at least one embodiment described herein for the use in testing a single circuit board under controlled conditions.

FIG. 2 depicts a testing apparatus in accordance with at least one embodiment described herein for use in the testing of multiple boards under controlled conditions.

### DETAILED DESCRIPTION

The various embodiments described herein generally relate to apparatuses, systems and/or methods for the individualized testing of circuit boards under individualized environmental conditions. It is to be appreciated that the various embodiments described herein are primarily described in the context of circuit boards and/or components utilized in the transmission and/or reception of radio frequency signals. However, the principles and concepts described herein may be used in conjunction with the testing of any device, system or component with respect to which such testing is desirably performed on an individualized or small batch basis and where it is desirable to more precisely control the environments in which such testing occurs. According to at least one embodiment, the test environment may be controlled with respect to one or more factors including, but not limited, to temperature, humidity, pressure, the incidence or absence of various forms of radiation, magnetism, electrical signals (e.g., those of a pulsing or steady state nature), radio frequency signals, light, thermal, or otherwise.

In one embodiment of a production and testing environment, apparatus, systems and methods are provided which facilitate low cost, and high speed testing of, for example, circuit boards, chips and other components (hereafter, collectively “boards”). It is to be appreciated that such boards may include one or many components and may be provided, for example, as test products, sub-assembly products, final products or otherwise. In one embodiment, such boards may be tested over a range of temperatures, in any state of such board's operating conditions. For example, the board may be tested in an on/off, recently powered on/off (cyclic testing), or other condition in order to mimic real-life operating conditions that such board may experience. Further, the range of conditions over which such board may be tested may be customized. For example, a first board might be tested over an operating range of −40 Celsius to +40 Celsius, with ten degree increments being applied, whereas a second board might be tested over the same range of temperatures with sudden spikes (heating or cooling) being applied, as might occur for a device expected to experience sudden and perhaps unpredictable changes in the conditions in which it is to operate. Other environmental conditions may also be controlled, for example, the humidity experienced by a board under pre-test, test and post-test conditions. It is to be appreciated that any environmental condition may be accommodated using the apparatus, systems and methods of the various embodiment described herein. Accordingly, at least one embodiment provides an apparatus, system and methodology capable of adjusting any desired and controllable environmental conditions for a board under test.

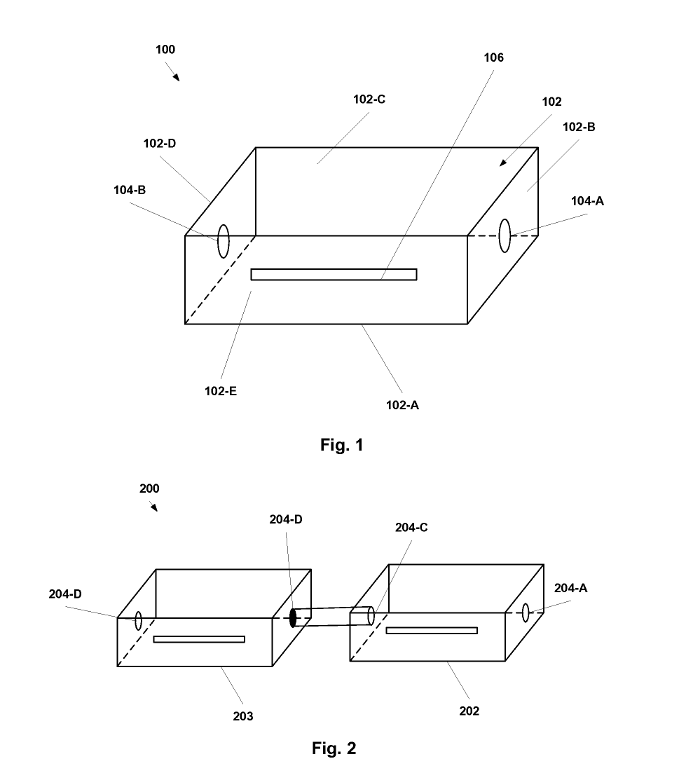

One embodiment of test apparatus in accordance with the descriptions provided herein, includes a clam shell type enclosure 100, as shown in FIG. 1. As shown, the apparatus may include a test cavity 102, which is surrounded by a floor 102-A, and a perimeter, which in this embodiment includes four walls 102-B, 102-C, 102D and 102-E and a lid (not shown in FIG. 1). The test cavity may be sealed off from any and/or all external environmental conditions, as desired. At least one of the lid, floor and/or perimeter sections (or portions thereof) may be movable, so as to permit entry into the test cavity. The movement of such lid and/or wall sections may be automated, semi-automated or manual. And, such movement may occur prior to, during and/or after test conditions—as desired for any given testing protocol.

It is to be appreciated, in other embodiments, the test cavity may be formed by any configuration of walls including, but not limited to, spherical structures, hexagon, pentagons or otherwise.

Each of the lid and/or one or more wall sections may be configured to emit or shield a board under test from any particular environmental concerns. For example, in one embodiment, each of the lid and walls may be configured so as to create a Faraday cage, whereby external to the test cavity electromagnetic signals, such as radio frequency (RF) signals are not allowed to penetrate into the test cavity. The methods for making a Faraday cage and/or otherwise shielding boards from electromagnetic, RF and/or other signals are well known in the art. Further, one or more of the lid and/or wall sections may be periodically, for example, intermittently reconfigured to as to provide/not provide the shielding desired from an external environmental condition. For example, to emulate the testing of a board anticipated to be exposed to varying RF conditions, one or more of the walls properties may be modified to permit the emission into the test cavity of external electromagnetic signals. Similarly, in another embodiment, RF and other signal conditions may be emulated by one or more internal emitters situated into the test cavity itself, with the lid and walls providing shielding and protection to operators external to such cavity. For example, a board anticipated to be utilized in conditions experiencing X-Ray or other forms of radiation commonly harmful to humans, may be configured to create within the test cavity itself such an X-Ray rich environment, while external to the test cavity, such conditions do not exist. Accordingly, it is to be appreciated that the lid and/or one or more of the walls may be configured using materials having desired properties.

The physical dimensions of the enclosure may be configured, for at least one embodiment, to be slightly larger than the board to be placed under test. In this manner, the enclosure desirably minimizes the amount of power, space, support and “insulation” needed to create a testing environment within the test cavity while respectively shielding the external environment from the test environment. Further, may configuring the enclosure at a size that is, per one embodiment, slightly larger than the board under test, it is to be appreciated that the environmental conditions within the test cavity may be modified, desirably at a higher rate and/or under greater control, than the conditions of presently available board testing apparatus.

The enclosure 100 may also be configured to have one or more access portals, such as portals 104-A and 104-B. Such portals may be used to input air, fluids, radiation or any other conceivable environmental modifier into the test cavity 102, wherein an “environmental modifier” is that which modifies from a first condition to a second condition and/or maintains one or more conditions inside the test cavity 102. An environmental modifier, for example, may include the pressure inside the chamber, with it being appreciated that an air compressor or a pump may increase, decrease or maintain, respectively, the ambient pressure inside the test cavity, including the creation of vacuum conditions or otherwise. Similarly, an environmental modifier may include the air temperature within the test cavity. For such an embodiment, the temperature of the test cavity 102 may be heated, cooled and/or maintained at any rate including, for example and not by way of limitation, at a rapidly changing rate, a steady state rate, a slow rate or any other desired rate of change. The changing of the environment within the cavity may be accomplished, for example, by utilizing portals 104-A and 104-B to move air through the chamber. Similarly, the temperature of the board under test (versus the temperature of the environment inside the test cavity) may also be monitored and controlled, as any given implementation of a testing protocol dictates. It is to be appreciated that the movement of air or any other environmental modifier, at any desired rate (including variable, random, fixed, gradual or otherwise) may be utilized to simulate any desired test conditions.

For at least one embodiment, it is also to be appreciated that the conditions within test cavity 102 may remain sterile (i.e., without any external influences being inserted into the chamber). Under such conditions, the temperature of the cavity itself, for example, may be influenced by conductive heating or cooling. Similarly, the volume and/or pressure of the chamber may be influenced by movable membranes, or otherwise. Accordingly, it is to be appreciated that the enclosure may be configured to meet any desired testing conditions.

The enclosure 100 may also be configured, in accordance with at least one embodiment, to include one or more interfaces 106, wherein an interface enables a board undergoing test to be controlled by an operator external to the test cavity. In the simplest of examples, an interface may include a simple power connection, by which the power applied to a board under test may be controlled by a person and/or machine external to the test cavity 102. In other embodiments, the interface may provide for the full control of a board under test, and may include one or more telemetry signals indicative of the operation of the board and/or environment existing inside the test cavity 102 at any given time. It is to be appreciated, the interface 106 utilized for any given embodiment is designed to support the board under test and the tests and environmental conditions to which such board is desired to be exposed, as in accordance with any given testing protocol. Further, suitable connectors may be used both internal and external to the enclosure 100 to facilitate the connection of the board to the interface 106 and/or the interface to one or more external devices or equipment.

Referring now to FIG. 2, in accordance with at least one embodiment, it is to be appreciated that the enclosures may be utilized in any desired combinations or permutations. For example, in FIG. 2, a combination of two enclosures 202 and 203 are shown wherein a single entrance portal 204-A is utilized to provide an environmental modifier into a first enclosure 202 and a single exit portal 204-B is utilized to remove the environmental modifier from the second enclosure 203. Portals 204-C and 204-D are suitably interconnected so as to simulate an ever varying environment within and between each of the enclosures 202 and 203. In another embodiment, not shown, it is to be appreciated that a bank of enclosures could be configured so that the environment experienced within each of their respective test cavities is the same. In such an embodiment, a plurality of environmental modifiers may be applied to or from each cavity via each enclosures respective entrance and/or exit portals. In yet another embodiment, the testing protocols applied to any given board, and the environmental modifiers applied to any corresponding enclosure, in a bank of enclosures, may be modified and/or staged. For example, a first board or series of boards (and/their respective enclosures) may be exposed to a first environmental modifier. This first environmental modifier may then be extracted from the first board or series of enclosures and applied to a second board or series of boards, and thereby effectively recycled and/or reused. Such a testing protocol may be desired, for example, when boards are to be exposed, for example, to specialized gasses, varying temperatures or the like. It is to be appreciated that such synchronization may facilitate a continuous or semi-continuous sequence of operations, such as cooling and/or heating, with each enclosure being controlled at varying conditions. Thus, unlike commonly available bank testing operations, the various embodiments described herein facilitate the accurate and varying collection of testing parameters as each board in each enclosure may be subjected to unique environmental modifiers at any given time, and in accordance with any given testing protocol.

1. An apparatus for testing a board, comprising:
a floor;
one or more perimeter wall sections;
a lid;
one or more access portals; and
one or more interfaces;
wherein the floor, perimeter wall sections and lid form a test cavity; and wherein an environmental modifier may be applied with respect to the test cavity using the one or more access portals; and wherein an operating condition of a board undergoing testing within the test cavity may be controlled utilized the one or more interfaces.

2. The apparatus of claim 1, wherein at least one of the floor, perimeter wall sections and lid is configured of a material designed to isolate the test cavity from an environmental condition external to the test cavity when the board is under test.

3. The apparatus of claim 2, wherein the environmental condition external to the test cavity from which isolation of the test cavity is provided when the board is under test is a thermal condition.

4. The apparatus of claim 2, wherein the environmental condition external to the test cavity includes one or more radio frequency signals.

5. The apparatus of claim 1, wherein the test cavity is sized to hold a single board.

6. The apparatus of claim 1, wherein the one or more interfaces include a power interface configured to provide electrical power to the board when the board is under test.

7. The apparatus of claim 6, wherein the one or more interfaces include a sensor interface configured to communicate signals from one or more environmental condition monitors to an external monitoring device, wherein the one or more environmental condition monitors are configured to monitor one or more environmental conditions inside the test cavity when the board is under test.

8. The apparatus of claim 7, wherein the one or more interfaces include a control interface configured to communicate one or more control signals by and between a board under test and an external control device.

9. The apparatus of claim 8, wherein the one or more control signals include one or more control signals utilized to control the operation of the board under test in accordance with a testing protocol.

10. The apparatus of claim 9, wherein the one or more access portals are configured to facilitate the application of one or more environmental modifiers to the test cavity.

11. The apparatus of claim 10, wherein the one or more environmental modifiers are applied to the test cavity while the board is electrically powered.

12. The apparatus of claim 10, wherein the one or more access portals are configured to facilitate the application of one or more thermal environmental modifiers, wherein upon application of the one or more thermal environmental modifiers the board within the test cavity is exposed to a change in temperature.

13. The apparatus of claim 10, wherein the one or more access portals are configured to facilitate the application of one or more radio frequency environmental modifiers, wherein upon application of the one or more radio frequency environmental modifiers the board within the test cavity is exposed to a change in the radio frequency environment.

14. The apparatus of claim 1, further comprising an internal emitter.

15. The apparatus of claim 14, wherein the internal emitter is configured to emit a radio frequency signal when the internal emitter is activated.

16. A process for testing a plurality of boards comprising:
arranging a plurality of enclosures, one for each of the plurality of boards, wherein each enclosure has a floor, a perimeter of one or more wall sections, a lid, one or more access portals and one or more interfaces, wherein the floor, perimeter wall sections and lid form a test cavity; and wherein an environmental modifier may be applied with respect to the test cavity using the one or more access portals; and wherein an operating condition of a board undergoing testing within the test cavity may be controlled utilized the one or more interfaces;
applying a first environmental modifier to a first of the plurality of enclosures;
applying a second environmental modifier to a second of the plurality of enclosures;
when the plurality of enclosures includes more than two enclosures, applying an Nth environmental modifier to each of the remaining of the plurality of enclosures; and
sequencing the application of each of the first environmental modifier, the second environmental modifier and the Nth environmental modifier to each of the plurality of enclosures.

17. The process of claim 16, wherein the sequencing of the plurality of environmental modifiers applied to each of the plurality of enclosures results in each of the plurality of enclosures receiving the same sequence of environmental modifiers.

18. The process of claim 16, wherein the sequencing of the plurality of environmental modifiers applied to the plurality of enclosures results in the application of one or more of the plurality of environmental modifiers to at least one of the plurality of enclosures in a sequence that is unique with respect to at least one other of the plurality of enclosures.

19. The process of claim 16, wherein the sequencing of the plurality of environmental modifiers applied to each of the plurality of enclosures results in the application of one or more of the plurality of environmental modifiers in an order that is unique for each of the plurality of enclosures with respect to the sequencing of the plurality of environmental modifiers as applied to each of the other of the plurality of enclosures.

20. The process of claim 16, wherein each of the environmental modifiers modifies a temperature of a test cavity within at least one of the enclosures over temperature range of −40 Celsius to +85 Celsius.
